(19) United States
(12) Patent Application Publication
(10) Pub. No.: US 2026/0118455 A1
(43) Pub. Date: Apr. 30, 2026

(54) SYSTEM AND METHOD FOR FLEXIBLE, CUTTABLE RADIO-FREQUENCY COILS FOR A MAGNETIC RESONANCE IMAGING SYSTEM

(71) Applicant: SYNAPTIVE MEDICAL INC., Mississauga (CA)

(72) Inventors: Ian Robert Oliphant CONNELL, Toronto (CA); Alex Gyles PANTHER, Toronto (CA); Gilbert THEVATHASAN, Brampton (CA); Chad Tyler HARRIS, Toronto (CA)

(21) Appl. No.: 19/346,445

(22) Filed: Sep. 30, 2025

Related U.S. Application Data
(60) Provisional application No. 63/712,430, filed on Oct. 26, 2024.

(51) Int. Cl. G01R 33/34; G01R 33/3415; G01R 33/36

(52) U.S. Cl. CPC G01R 33/34084; G01R 33/3415; G01R 33/3621

(57) ABSTRACT

A radio-frequency (RF) coil system for a magnetic resonance imaging (MRI) system includes a plurality of flexible RF coil elements, each formed from a thin, malleable conductive substrate; a monitoring circuit electrically coupled to each RF coil element for detecting a disconnection of any RF coil element from the remaining active coil elements; a reconfiguration module dynamically adapting a plurality of imaging parameters based on the remaining active RF coil elements; and at least one detachable preamplifier circuit configured to be operatively coupled to and decoupled from at least one RF coil element.

### CROSS-REFERENCE TO RELATED APPLICATION(S)

The document is a Nonprovisional Patent application claiming the benefit of and priority to, U.S. Provisional Patent Application Ser. No. 63/712,430, entitled “SYSTEM AND METHOD FOR FLEXIBLE, CUTTABLE RADIO-FREQUENCY COILS FOR A MAGNETIC RESONANCE IMAGING SYSTEM”, filed on Oct. 26, 2024, the application hereby incorporated by reference in their entirety.

### TECHNICAL FIELD

The field of the invention is systems and methods for magnetic resonance imaging (MRI), in particular RF (radiofrequency) coils for MRI.

### BACKGROUND

This disclosure pertains to radio-frequency (RF) coils. The RF coil is a resonant structure that has two functions: (1) excitation of the sample during a magnetic resonance imaging (MRI) acquisition, and (2) signal reception during the precessional relaxation of nuclei excited in step (1).

It is possible for the two functions mentioned above to be performed by the same RF coil. However, the most common RF systems employ two independent RF coils: a transmit-only RF coil and a receive-only RF coil.

The receive RF coil is located in close proximity to the subject-specifically the patient anatomy to be investigated. This achieves a tight coupling between the coil elements and the received signal, thus increasing the magnitude of the received signal. The most sophisticated implementations of RF receive coils are optimized such that the signal-to-noise (SNR) ratio for the coil is optimized for patient anatomy, scanner parameters and intended use cases during routine imaging (parallel image reconstruction, by one example). When imaging at mid-field strengths (1.0 Tesla and below), due to the intrinsic loss in nuclear polarization, optimization of the receive coil is of paramount importance for reconstructing images of clinical SNR and spatial resolution.

The location of a tight-fitting receive coil, although excellent for MRI performance, provides challenges for either intra-operative procedures or image-guided procedures where MRI is the imaging modality.

Traditional rigid RF coils provide excellent SNR but limit access to the patient, making them impractical for intraoperative or interventional MRI. The present invention solves this by enabling a flexible, reconfigurable, and optionally disposable RF coil array. A cuttable and flexible, intelligent RF coil design is a strong compromise between MRI performance and therapeutic access.

### BRIEF DESCRIPTION OF THE DRAWINGS

FIG. 1 is a diagram illustrating an exemplary rigid RF coil assembly.

FIG. 2A is a diagram illustrating an exemplary swimmer cap for a coil shape.

FIG. 2B is a diagram illustrating an exemplary balaclava for a coil shape.

FIG. 3 is a diagram illustrating an example of a flexible receiver coil with detachable and reusable preamplifier circuit.

FIG. 4A is a diagram illustrating a flexible receiver coil in a two-loop configuration.

FIG. 4B is a diagram illustrating a flexible receiver coil in a three-loop configuration.

### SUMMARY

A system and method for flexible, cuttable radio frequency coils for a magnetic resonance imaging (MRI) system is provided. A cuttable, flexible and intelligent RF coil design using thin and malleable flexible conductors (e.g., conductive thread, ultra-flex PCB board, or coaxial cable) allows the coil to be ‘cut’ into the desired arrangement such that the patient can be accessed.

In some aspects, the techniques described herein relate to a radio-frequency (RF) coil system for a magnetic resonance imaging (MRI) system, including: a plurality of flexible RF coil elements, each including a thin, malleable conductive substrate; a monitoring circuit electrically coupled to each RF coil element, wherein the monitoring circuit detects a disconnection of any RF coil element from remaining active coil elements of the coil system; a reconfiguration module that dynamically adapts a plurality of imaging parameters based on the remaining active RF coil elements; and at least one detachable preamplifier circuit configured to be operatively coupled to and decoupled from at least one of the RF coil elements.

In some aspects, the techniques described herein relate to a method for performing MRI using an RF coil system, including: positioning the RF coil system including a plurality of connected RF coil elements, on a patient; disconnecting at least one RF coil element from remaining active RF coil elements; detecting the disconnection via a monitoring circuit; and performing MRI using the remaining active RF coil elements.

### DETAILED DESCRIPTION

The present disclosure relates to a radio-frequency (RF) coil system for use in a magnetic resonance imaging (MRI) environment, and more specifically to a system and method for flexible, cuttable RF coils that allow for therapeutic access during image-guided procedures without sacrificing image quality or system performance.

Conventional RF coils used in MRI are typically rigid and fixed in geometry. These traditional designs pose challenges in surgical or interventional MRI environments where access to the patient's body is required. The disclosed system addresses this problem by providing an array of flexible coil elements that can be cut or detached as needed, with real-time system feedback and dynamic reconfiguration, thereby optimizing both signal-to-noise ratio (SNR) and procedural access.

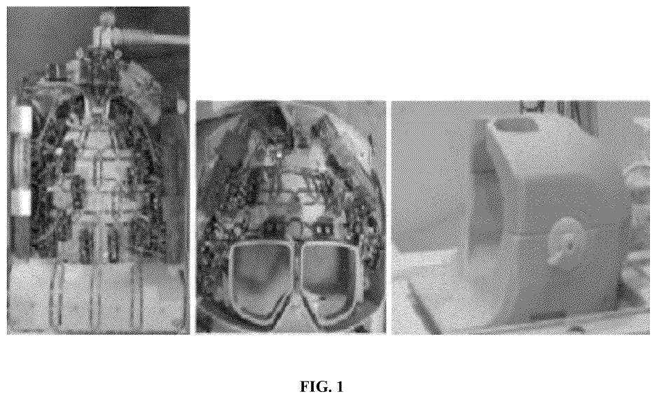

The present disclosure encompasses any multi-channel RF coil used for transmit, transmit-receive or receive functions. The RF coil is comprised of a plurality of individual resonating elements as shown in FIG. 1. FIG. 1 is a diagram illustrating an exemplary rigid RF coil assembly. In FIG. 1, a receive-only RF coil is shown, however, the configuration of the individual elements in the array can also be suitable for transmit-only and transmit-receive functions. Each one of these individual elements in the array operates independently and has monitoring to detect the presence of the array elements.

The system of the present disclosure includes multiple RF coil elements, each fabricated using thin, malleable conductive materials or substrate, including but not limited to:
Conductive thread,
Ultra-flex printed circuit boards (PCBs), or
Coaxial cables with a low copper weight.

According to the disclosure, the low copper weight and thin substrate allow the coil to be ‘cut’ into the desired arrangement such that the patient can be accessed.

Each coil element is shaped into a loop and arranged in a configuration that ensures overlapping field-of-view regions, enabling robust parallel imaging and signal redundancy. This overlap allows for individual coil elements to be disabled or removed without creating image voids.

Due to overlap in the fields-of-view of the array elements, it is possible to omit one or two elements such that a full image of the anatomy can still be produced, however the vacant portions of the array allow access to the patient through the RF coil. These access points are then used for delivering therapeutics or performing operations on the patient.

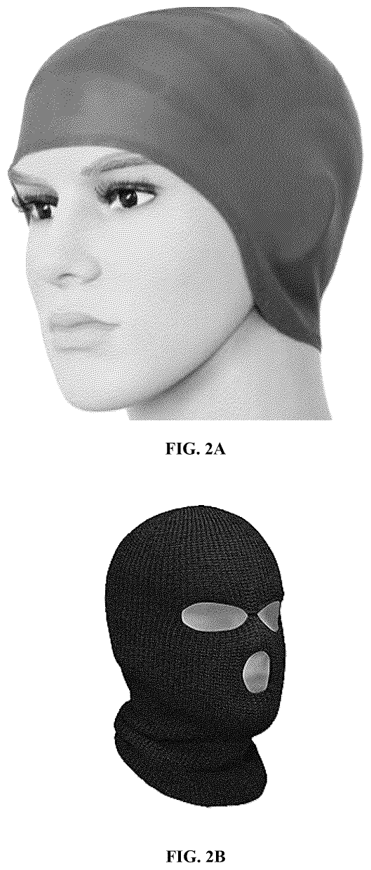

The thin and flexible nature of the coil substrate allows the array to conform tightly to various anatomical surfaces. When the coil is placed on the patient, it is flexible in nature and maintains close contact to the patient's anatomy. Unlike conventional rigid coils, the flexible array may take a form of a flexible housing analogous to a swimmer's latex cap (FIG. 2A) or a stretchable balaclava (FIG. 2B) when applied to the head or other body parts. FIG. 2A is a diagram illustrating an exemplary swimmer cap. FIG. 2B is a diagram illustrating an exemplary balaclava.

Importantly, the conductive paths of the coil loops can be physically cut using scissors or other surgical instruments, creating custom openings in the coil array. The coil elements are configured to be cut without requiring reassembly of the remaining active RF coil elements. The custom openings can be used to facilitate surgical access, for example, for:
Surgical incisions,
Biopsy access,
Drug delivery, or
Instrumentation placement (e.g., catheters or scopes).

Each coil element is monitored by a monitoring circuit electrically coupled to each coil element such that upon removal of the coil element from the array via cutting, the software is notified and can adjust itself to reduce the total channel count. One example of this monitoring is described here: Located on each coil is a pathway for direct current (DC). Upon cutting a coil element, the DC pathway is opened. The open-circuit is then monitored by an external microcontroller which automatically assigns the remaining coil elements available for imaging. This DC pathway can be designed to include already required components such as PIN diodes for element detuning.

Each coil element includes a DC monitoring pathway integrated into the loop. When an element is cut or disconnected, the DC circuit becomes open, which is detected by an external microcontroller or coil controller reconfiguration module.

The reconfiguration module performs the following functions to dynamically adapt a plurality of imaging parameters based on the remaining active coil elements:
Identifies which coil elements are active,
Recalculates the total number of receive channels,
Dynamically reassigns signal routing to avoid the disconnected coil, and
Updates MRI system parameters to account for new field-of-view geometry.

This ensures seamless imaging even as the coil array is modified in real time.

Another embodiment can include only a flexible ‘skeleton’ of the coil arrangement. This type of structure can similarly be cut and shaped to the procedure requirements.

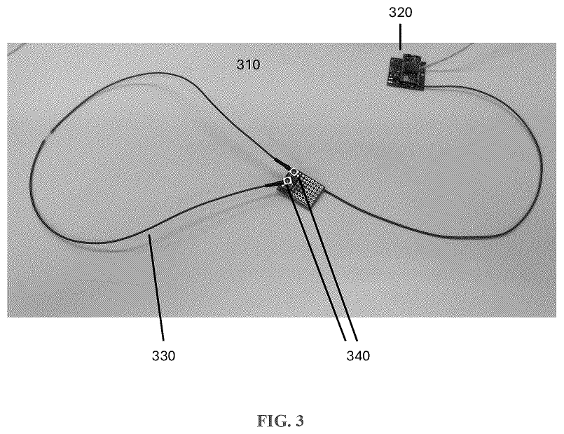

As illustrated in FIG. 3, in one embodiment, each coil element 310 includes a detachable preamplifier circuit 320, which can be operatively coupled to and decoupled from an RF coil element. The preamplifier circuit 320 may include a quick-connect terminal for rapid attachment and detachment. The preamplifier circuit 320 can be disconnected and reused after a coil element is cut or replaced, reducing per-patient coil cost. This modularity supports single-use disposable loop elements 330 while retaining expensive electronic components such as the preamplifier circuit 320 for repeated use.

The preamplifier circuit 320 may include:
Low-noise amplifier (LNA) circuitry,
Detuning circuits (e.g., positive-intrinsic-negative (PIN) diode arrays),
Connector interfaces for quick attachment and detachment,
Optional shielding to reduce electromagnetic interference (EMI).

The preamplifier circuit 320 can be detachable from the loop element 330 and the loop element 330 can be detached from one or both ends 340 and then re-attached. In this way, the preamplifier circuit 320 can be re-used after a coil element has been cut away, thereby allowing the “disposable” component of the array to be cheaper to manufacture.

An example of a flexible array with detachable pre-amplifier circuit 320 and detachable element ends 340 is shown in FIG. 3. According to FIG. 3, the loop element 330 can be disconnected to allow winding around an object such as a head-fixation device.

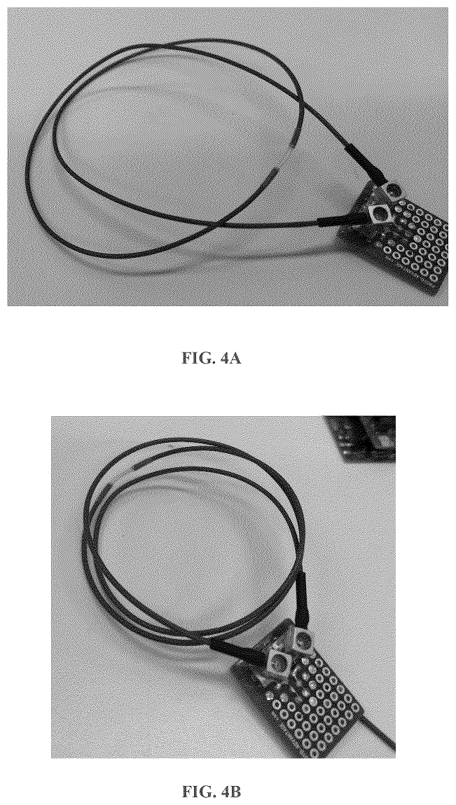

Furthermore, an advantage of a loop element 330 with detachable ends 340 is that one can “wind-up” the loop element. For example, a two-loop configuration (FIG. 4A) or a three-loop configuration (FIG. 4B). As the coil is “wound-up”, the anatomical coverage is reduced, but the local SNR increases. A tighter winding increases local SNR by focusing the field, while a larger loop provides greater anatomical coverage. The coil elements can be wound into different loop configurations, depending on the desired trade-off between anatomical coverage and local SNR.

The detachable nature of the loop ends 340 allows the loop element 330 to be wrapped around a pre-installed device, such as a head fixation pin or surgical frame. This is particularly valuable in intraoperative MRI, where head fixation may occur before the coil is placed. In this scenario, a detachable loop element 330 will allow maximum coverage without adjustment of the fixation device.

This ability to adapt the loop geometry to existing patient hardware allows:
Avoiding repositioning of surgical instruments,
Maximizing coverage without compromising surgical access, and
Reducing procedural setup time.

The system may be operated through firmware-controlled microcontrollers or integrated into the MRI system's RF management software. A processor (e.g., a microcontroller, ASIC, or FPGA) manages:
Coil element detection,
Real-time reconfiguration,
SNR optimization,
Signal demodulation pathways.

The system may optionally include a graphical user interface (GUI) to visualize which coil elements are active or disconnected.

Coil element data (such as ID (identification), activation state, SNR contribution) may be communicated to the MRI console through:
A wired bus (e.g., SPI, 12C, CAN), or
Wireless communication (e.g., BLE or RF link) in shielded settings.

The coil element data, including ID for each element, may be software-detected for individualized control of the coil element.

Acceptable conductive materials for manufacture include:
Silver-coated threads for high flexibility,
Copper-trace on polyimide substrate for ultra-flex PCB,
Braided coaxial cable for durability and shielding.

Coils are insulated with a biocompatible polymer coating (e.g., silicone, polyurethane) and may include EMC shielding to comply with safety standards for RF emissions in MRI suites.

While described in the context of neuroimaging, the disclosed RF coil system can be adapted for other anatomies, including but not limited to:
Spine,
Breast,
Abdomen,
Extremities.

The disclosed RF coil system may also be adapted for use in veterinary MRI, hybrid PET-MRI, or portable MRI devices.

A method for using the RF coil system includes positioning the RF coil system, including a plurality of connected RF coil elements, which may be referred to as a loop or an array, on a patient, disconnecting at least one of the RF coil elements from the remaining active RF coil elements, detecting the disconnection via a monitoring circuit, and performing MRI using the remaining active coil elements.

At least some aspects disclosed may be embodied, at least in part, in software. That is, some disclosed techniques and methods may be carried out in a computer system or other data processing system in response to its processor, such as a microprocessor, executing sequences of instructions contained in a memory, such as read-only memory (ROM), volatile random access memory (RAM), non-volatile memory, cache or a remote storage device.

The functions described herein may be stored as one or more instructions on a processor-readable or computer-readable medium. The term “computer-readable medium” refers to any available medium that can be accessed by a computer or processor. By way of example, and not limitation, such a medium may comprise RAM, ROM, EEPROM, flash memory, CD-ROM or other optical disk storage, magnetic disk storage or other magnetic storage devices, or any other medium that can be used to store desired program code in the form of instructions or data structures and that can be accessed by a computer. It should be noted that a computer-readable medium may be tangible and non-transitory. As used herein, the term “code” may refer to software, instructions, code or data that is/are executable by a computing device or processor. A “module” can be considered as a processor executing computer-readable code.

A processor as described herein can be a general-purpose processor, a digital signal processor (DSP), an application specific integrated circuit (ASIC), a field programmable gate array (FPGA) or other programmable logic device, discrete gate or transistor logic, discrete hardware components, or any combination thereof configured to perform the functions described herein. A general-purpose processor can be a microprocessor, but in the alternative, the processor can be a controller, or microcontroller, combinations of the same, or the like. A processor can also be implemented as a combination of computing devices, e.g., a combination of a DSP and a microprocessor, a plurality of microprocessors, one or more microprocessors in conjunction with a DSP core, or any other such configuration. Although described herein primarily with respect to digital technology, a processor may also include primarily analog components. In some embodiments, a processor can be a graphics processing unit (GPU). The parallel processing capabilities of GPUs can reduce the amount of time for training and using neural networks (and other machine learning models) compared to central processing units (CPUs). In some embodiments, a processor can be an ASIC including dedicated machine learning circuitry custom-build for one or both of model training and model inference. The disclosed or illustrated tasks can be distributed across multiple processors or computing devices of a computer system, including computing devices that are geographically distributed.

The methods disclosed herein comprise one or more steps or actions for achieving the described method. The method steps and/or actions may be interchanged with one another without departing from the scope of the claims. In other words, unless a specific order of steps or actions is required for proper operation of the method that is being described, the order and/or use of specific steps and/or actions may be modified without departing from the scope of the claims.

The specific embodiments described above have been shown by way of example and understood is that these embodiments may be susceptible to various modifications and alternative forms. Further understood is that the claims are not intended to be limited to the forms disclosed, but rather to cover all modifications, equivalents, and alternatives falling within the spirit and scope of this disclosure. While the foregoing written description of the system enables one of ordinary skill to make and use what is considered presently to be the best mode thereof, those of ordinary skill will understand and appreciate the existence of variations, combinations, and equivalents of the specific embodiment, method, and examples herein. The system should therefore not be limited by the above-described embodiment, method, and examples, but by all embodiments and methods within the scope and spirit of the system. Thus, the present disclosure is not intended to be limited to the implementations shown herein but is to be accorded the widest scope consistent with the principles and novel features disclosed herein.

Information as herein shown and described in detail is fully capable of attaining the above-described object of the present disclosure, the presently preferred embodiment of the present disclosure, and is, thus, representative of the subject matter which is broadly contemplated by the present disclosure. The scope of the present disclosure fully encompasses other embodiments which may become obvious to those skilled in the art, and is to be limited, accordingly, by nothing other than the appended claims, wherein any reference to an element being made in the singular is not intended to mean “one and only one” unless explicitly so stated, but rather “one or more.” All structural and functional equivalents to the elements of the above-described preferred embodiment and additional embodiments as regarded by those of ordinary skill in the art are hereby expressly incorporated by reference and are intended to be encompassed by the present claims.

Moreover, no requirement exists for a system or method to address each problem sought to be resolved by the present disclosure, for such to be encompassed by the present claims. Furthermore, no element, component, or method step in the present disclosure is intended to be dedicated to the public regardless of whether the element, component, or method step is explicitly recited in the claims. However, various changes and modifications in form, material, work-piece, and fabrication material detail may be made, without departing from the spirit and scope of the present disclosure, as set forth in the appended claims, as may be apparent to those of ordinary skill in the art, are also encompassed by the present disclosure.

What is claimed is:

1. A radio-frequency (RF) coil system for a magnetic resonance imaging (MRI) system, comprising:
a plurality of flexible RF coil elements, each comprising a thin, malleable conductive substrate;
a monitoring circuit electrically coupled to each RF coil element, wherein the monitoring circuit detects a disconnection of any RF coil element from remaining active coil elements of the coil system;
a reconfiguration module that dynamically adapts a plurality of imaging parameters based on the remaining active RF coil elements; and
at least one detachable preamplifier circuit configured to be operatively coupled to and decoupled from at least one of the RF coil elements.

2. The RF coil system of claim 1, wherein the flexible conductive substrate comprises conductive thread, an ultra-flex PCB, or a coaxial cable.

3. The RF coil system of claim 1, wherein the monitoring circuit comprises a direct current (DC) pathway that opens upon the disconnection of the RF coil element.

4. The RF coil system of claim 3, wherein the DC pathway comprises a positive-intrinsic-negative (PIN) diode.

5. The RF coil system of claim 1, wherein the preamplifier circuit is configured for reuse after the disconnection of the RF coil element.

6. The RF coil system of claim 1, further comprising a flexible housing shaped as a cap or a balaclava to conform to patient anatomy.

7. The RF coil system of claim 1, wherein the coil elements are configured to be cut without requiring reassembly of the remaining active RF coil elements.

8. The RF coil system of claim 1, wherein the reconfiguration module is implemented by a microcontroller.

9. The RF coil system of claim 1, wherein the coil elements are arranged in an array with an imaging coverage comprising overlapping field-of-view regions.

10. The RF coil system of claim 9, wherein the imaging coverage is maintained upon removal of one or more coil elements.

11. The RF coil system of claim 1, wherein the coil elements are configured in a two-loop or a three-loop geometry.

12. The RF coil system of claim 11, wherein a local signal-to-noise ratio (SNR) increases and anatomical coverage is reduced.

13. The RF coil system of claim 1, wherein the coil element is configured to wrap around a fixed object.

14. The RF coil system of claim 1, wherein the preamplifier circuit includes quick-connect terminals for rapid attachment and detachment.

15. The RF coil system of claim 1, further comprising an MRI system configured to operate using the remaining active coil elements.

16. A method for performing MRI using an RF coil system, comprising:
positioning the RF coil system comprising a plurality of connected RF coil elements, on a patient;
disconnecting at least one RF coil element from remaining active RF coil elements;
detecting the disconnection via a monitoring circuit; and
performing MRI using the remaining active RF coil elements.

17. The method of claim 16, further comprising reusing a detached preamplifier circuit with a replacement coil element.

18. The method of claim 16, wherein the coil system is adjusted in real time by an MRI software in response to the detected disconnection.

19. The method of claim 16, wherein the RF coil elements are disconnected to facilitate a surgical access.

20. The method of claim 16, wherein the RF coil elements include software-detected element identifications for individualized control.
